(19) United States
(12) Patent Application Publication
(10) Pub. No.: US 2023/0328942 A1
(43) Pub. Date: Oct. 12, 2023

(54) Alloy of extremely low magnetic noise

(71) Applicants: University of Iowa Research Foundation, Iowa City, IA (US); The University of British Columbia, Vancouver (CA)

(72) Inventors: David M Miles, Iowa City, IA (US); Saul Brian Barry Narod, Vancouver (CA)

(73) Assignees: University of Iowa Research Foundation, Iowa City, IA (US); The University of British Columbia, Vancouver, BC (CA)

(21) Appl. No.: 17/699,895

(22) Filed: Mar. 21, 2022

Related U.S. Application Data
(60) Provisional application No. 63/164,045, filed on Mar. 22, 2021.

(51) Int. Cl. H05K 9/00; G01R 33/00

(52) U.S. Cl. CPC H05K 9/0075; G01R 33/0047; G01R 33/0052; G01R 33/04

(57) ABSTRACT

A metal alloy is provided which includes by weight percentage of the metal alloy, 28 to 55 percent copper, 45 to 63 percent nickel, and 4 to 10 percent iron. The metal alloy may be weight percentage 28 percent copper, 62 percent nickel, and 10 percent iron. The metal alloy may be formed into a foil which may have a thickness of 100 μm or less or 50 μm or less. A magnetic field instrument may include a magnetometer core body formed from one or more layers of the foil. The magnetometer core body may be a ring core or a racetrack core. The magnetic field instrument may further include a sense winding and may further include a drive winding. The magnetic field instrument may be a fluxgate magnetometer.

### RELATED APPLICATIONS

This application claims priority to U.S. Provisional Patent Application No. 63/164,045, filed Mar. 22, 2021, hereby incorporated by reference in its entirety.

### FIELD OF THE INVENTION

The present invention relates to a permalloy and its use. More particularly, but not exclusively, the present invention relates to a permalloy with extremely low magnetic noise which may be used in magnetic field instruments such as magnetometers or for magnetic shielding.

### BACKGROUND

Although the present invention is not limited to magnetic instruments such as fluxgate magnetometers, for purposes of discussion, fluxgate magnetometers provide context of one application for which new alloys with improved characteristics are desirable. Fluxgate magnetometers are essential tools for geophysics, mineral exploration, space physics, and military sensing providing high precision magnetic field measurements. Despite their ubiquitous use, the origin of the intrinsic magnetic noise in a fluxgate is poorly understood and, in some cases, the key research appears to have been lost to history. Fluxgates form a measurement by modulating (gating) the local magnetic field by periodically magnetically saturating a piece of ferromagnetic material. The instrumental noise floor is therefore limited by the intrinsic magnetic noise of this material as it enters magnetic saturation.

Therefore, what is needed is a new material and use of the material in magnetometers or other applications.

### SUMMARY

Therefore, it is a primary object, feature, or advantage of the present invention to improve over the state of the art.

It is a further object, feature, or advantage of the present invention to provide a permalloy which has low noise performance when used as a sensor magnetometer core such as in a fluxgate magnetometer sensor.

It is a still further object, feature, or advantage of the present invention to provide a permalloy which has high power efficiency and thus lower power requirements when used as a sensor magnetometer core such as in a fluxgate magnetometer sensor.

Another object, feature, or advantage of the present invention is to provide an improved fluxgate magnetometer.

Another object, feature, or advantage is to provide an alloy which may be used for magnetic shielding.

One or more of these and/or other objects, features, or advantages of the present invention will become apparent from the specification and claims that follow. No single embodiment need provide each and every object, feature, or advantage. Different embodiments may have different objects, features, or advantages. Therefore, the present invention is not to be limited to or by any objects, features, or advantages stated herein.

According to one aspect a metal alloy is provided which includes by weight percentage of the metal alloy, 28 to 55 percent copper, 45 to 63 percent nickel, and 4 to 10 percent iron. The metal alloy may be weight percentage 28 percent copper, 62 percent nickel, and 10 percent iron. The metal alloy may be formed into a foil which may have a thickness of 100 μm or less. The metal alloy may be formed into a foil which may have a thickness of 50 μm or less. A magnetic field instrument may include a magnetometer core body formed from one or more layers of the foil. The magnetometer core body may be a ring core or a racetrack core or of other geometry. The magnetic field instrument may further include a sense winding and may further include a drive winding. The magnetic field instrument may be a fluxgate magnetometer.

According to another aspect, a magnetic field instrument may include a magnetometer core body formed from a permalloy comprising copper, iron, and nickel. The magnetic field instrument further includes a first set of coil turns around the magnetometer core body forming a sense winding. The permalloy may comprise a plurality of layers of permalloy foil. The permalloy may consist of by weight percent of the permalloy, 28 to 55 percent copper, 45 to 63 percent nickel, and 4 to 10 percent iron. Each of the plurality of layers of the permalloy foil may have a thickness of 100 μm or less.

According to another aspect, a magnetic field instrument is provided which includes a magnetometer core body formed from one or more layers of permalloy foil consisting of by weight percent of the permalloy, 28 to 55 percent copper, 45 to 63 percent nickel, and 4 to 10 percent iron. Each of the layers of the permalloy foil may have a thickness of 100 μm or less or 50 μm or less. The magnetic field instrument further includes a first set of coil turns around the magnetometer core body forming a sense winding. The magnetometer core body may be a ring core or a racetrack core. The magnetic field instrument may further include electronics operatively connected to the sense winding. The magnetic field instrument may be a fluxgate magnetometer.

According to another aspect, a method of manufacturing a magnetic field instrument includes forming metal alloy comprising by weight percentage of the metal alloy, 28 to 55 percent copper, 45 to 63 percent nickel, and 4 to 10 percent iron, rolling the metal alloy to form a foil, and constructing a magnetometer core using the foil. The method may further include heat treating the magnetometer core. The method may further include adding a sense winding to the magnetometer core. The method may further include adding a drive winding to the magnetometer core.

### BRIEF DESCRIPTION OF THE DRAWINGS

Illustrated embodiments of the disclosure are described in detail below with reference to the attached drawing figures, which are incorporated by reference herein.

FIG. 1 is a set of photographs of permalloy which was manufactured starting from high-purity source powders that are mixed (a) and then melted together (b) via one hour at 1550° C. The resulting ingot is flattened in a hydraulic press (c), machined rectangular, and successively cold-rolled into 100 and the 50 μm foil (d).

FIG. 2 illustrates dimensions for one embodiment of a machined ferromagnetic foil which may be used in construction of the racetrack core.

FIG. 3 shows the assembly of a 1″ ring-core illustrated by (1a) render of principle components, (1b) photo of main components, (1c) assembled ring-core prior to application of drive-winding, and (1d) wound ring-core. Panels (2a-d) show the same steps for the race-track geometry core.

FIG. 4A is an illustrative ideal heat treatment—adapted from Miles et al., (2019).

FIG. 4B illustrates real-world heat-treatments. Time is normalized to the point when the material was hot loaded into the furnace indicated by the temperature dip.

FIG. 5 is a photograph of an experimental setup used to characterise core noise performance: five-layer mumetal shield with embedded solenoid, test fixtures for 1″ ring-core and racetrack cores, and single and benchtop magnetometer electronics.

FIG. 6 illustrates (Top) Drive current periodically saturating the ring. (Middle) Output of the pre-amplifier. (Bottom) Output of bandpass filter at 2 F frequency. Different lines show modulation due to different applied fields.

FIG. 7 is an example noise floor plot for core RT0013 (6-81, 50 μm, 1150° C. dwell). Note that the noise trend below ˜1 Hz appears to be significantly below the expected 1/F. The narrow-band feature 1 Hz is instrumental and related to 1 sps packetization and transmission over a USB interface.

FIG. 8A shows at top a photograph of 50 μm 6-81 Mo permalloy coupon heat treated at 1200° C. Major increments in the graticule show 1 mm spacing.

FIG. 8B shows a distribution of chord lengths (proxy for grain size) as determined visually using the intercept method.

FIG. 9A shows 1″ ring-core magnetic noise at 1 Hz plotted against the dwell temperature used in their heat treatment.

FIG. 9B shows 1″ ring-core magnetic noise at 0.1 Hz plotted against the dwell temperature used in their heat treatment.

FIG. 9C shows 1″ ring-core cord length as a proxy for grain size plotted against the dwell temperature used in their heat treatment.

FIG. 9D shows 1″ ring-core power required to drive each ring plotted against the dwell temperature used in their heat treatment.

FIG. 9E shows 1″ racetrack magnetic noise at 1 Hz plotted against the dwell temperature used in their heat treatment.

FIG. 9F shows 1″ racetrack magnetic noise at 0.1 Hz plotted against the dwell temperature used in their heat treatment.

FIG. 9G shows 1″ racetrack cord length as a proxy for grain size plotted against the dwell temperature used in their heat treatment.

FIG. 9H shows 1″ racetrack power required to drive each ring plotted against the dwell temperature used in their heat treatment.

FIG. 10 shows standard heat treatment with slow post-disordering cool compared to direct cooling.

FIG. 11 is comparison of ring-cores manufactured with an initial standard heat treatment (solid) versus those with a direct cooling (dashed). Heat treatments two and three were each 100 hours at 100° C.

FIG. 12A, FIG. 12B, FIG. 12C, and FIG. 12D show cord-size histograms for each material and thickness showing the effect of heat-treatment temperature on grain size.

FIG. 13 shows magnetic noise and power consumption as a function of number of foil layers.

FIG. 14 is a histogram of noise distribution for 20 cores.

FIG. 15 provides photographs of each coupon showing grain size. Major ticks in the graticules show 1 mm spacing.

FIG. 16 shows cord-size distribution for each foil coupon.

FIG. 17 illustrates alloy samples which have been fabricated for analysis following the zero magnetostriction Cu alloy regime from Auwers and Neumann (1935). Prototype fluxgate cores have been fabricated at 28-60 Cu, 33-58 Cu, 39-54 Cu, and 45-50 Cu and characterized for intrinsic magnetic noise and drive power consumption.

FIG. 18 illustrates preliminary tests of along the Cu—Ni zero magnetostriction line showing lower magnetic noise and lower power consumption with increasing Cu composition up to 45-50 Cu.

FIG. 19 is a block diagram of one example of a magnetic field instrument which may use the metal allow shown and described.

### DETAILED DESCRIPTION

### 1 Introduction

Fluxgate magnetometers (Fornacon et al., 1999; Primdahl, 1979; Snare, 1998) provide sensitive and highly-stable measurements of the local DC and low frequency magnetic field and have a variety of applications ranging from geophysics, space-physics and space-weather monitoring, to marine and military sensing. The noise floor of a fluxgate is typically limited by the intrinsic magnetic noise of a magnetometer core that is periodically driven into magnetic saturation to modulate the local magnetic field. Much of the early work developing low-noise cores was carried out in the 1960s for military applications (e.g., Scanlon, 1966) and is not available in the scholarly literature. This work by the US Naval Surface Weapons Center (NSWC) White Oak (now a Department of Agriculture facility) and Infinetics Inc. (Scarzello et al., 2001) resulted in the standard S1000 fluxgate core. A one-inch ring-core manufactured from a thin (3 or 12 μm) foil of 6% molybdenum Permalloy with noise ranging from ˜4 to ˜20 pT/√Hz at 1 Hz. Müller (1998) and Musmann (2010) both describe more recent efforts achieving <5 pT noise using a 20 μm foil for similar Permalloy. However, none of these efforts provide enough details for the manufacturing process to be understood unambiguously or to fully understand the effect of various design choices on the performance of the resulting fluxgate core.

Recent results from (Narod, 2014) established a theoretical framework for the origin of magnetic noise and magnetic hysteresis in Permalloy foils. An initial effort (Miles et al., 2019) demonstrated and documented a preliminary manufacturing process for low noise (<10 pT) 1″ geometry ring-cores. This study expands on that work by examining the influence of foil thickness, heat treatment, geometry, and the Permalloy alloy with the goal of consistently producing lower-noise and lower-power fluxgate cores.

We present the results of an initial parameter sweep comparing the traditional 6% molybdenum alloy to a new 28% copper alloy. Each alloy is tested at both 100 and 50 μm foil thicknesses with thinner foils planned to be explored as our manufacturing capability improves. We explore the effect of the heat-treatment used to optimise magnetic noise by exploring six temperatures spanning 1000 to 1250° C. Fluxgate cores are manufactured in two geometries—the standard spiral-wound 1 in. ring-core and a new 6.45 mm×31.45 mm racetrack geometry using continuous foil washers. We explore the relationship between number of foil layers and both magnetic noise and power consumption. We examine the effect of an additional sub-Curie heat treatment at 100° C. on the intrinsic magnetic noise of the cores. We have standardised on using three layers of foil for most tests in both core geometries to simplify manufacturing. Consequently, we are not expecting exceptional noise performance in these rings; rather we want to understand trends and to optimize the manufacturing process.

We hypothesize that noise is influenced by their grain size developed in the permalloy in relation to the thickness of the foil. Specifically, that complete primary recrystallisation will result in lowering magnetic noise, whereas secondary recrystallisation will result in higher magnetic noise. We manufactured test coupons for every combination of material, thickness, and heat-treatment and characterized their grain size distribution to begin exploring this relationship.

### 2 Construction of Candidate Cores

All cores were manufactured from scratch at the University of Iowa. All permalloy alloys were melted and processed in house and all bobbins were manufactured and assembled based on in-house designs.

### 2.1 Production of Permalloy Alloy

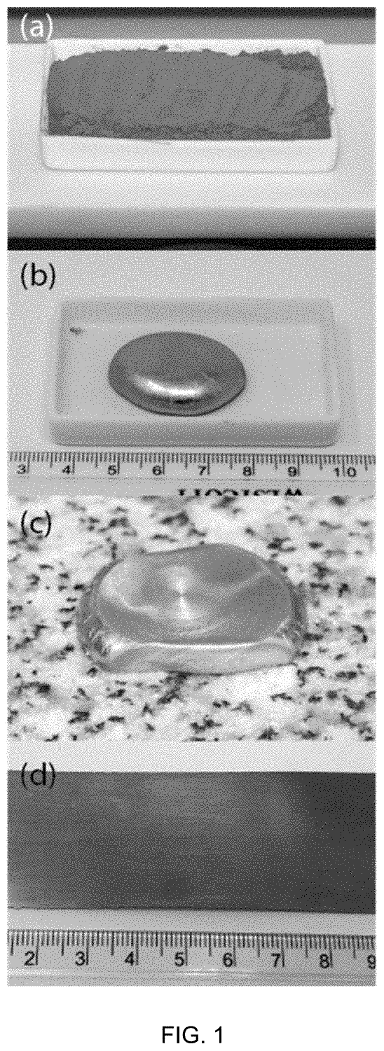

The fluxgate cores described here were based on permalloy manufactured at the University of Iowa. Casting small batches of permalloy in-house allows us to more easily and cost effectively explore new metallurgy such as the copper alloy described below. High-purity source powders were combined by ratio of weight, shaken to mix, and gently packed into an Alumina crucible (FIG. 1, panel (a)). The crucible was placed in the process furnace under a slow purge of a reducing atmosphere of 10% hydrogen diluted in argon. The process furnace ramped from room temperature to 1550° C. at 300° C.h⁻¹, held for one hour duration, and then returned to room temperature at 300° C.h⁻¹. The base powders combined to form a single uniform ingot (FIG. 1, panel (b))—the higher melting point molybdenum dissolving in the other liquid metals (e.g., Sene and Motta, 2013). Small cavities in the ingot were sometimes observed in the face contacting the crucible. A vacuum purge while the furnace was at 1550° C. did not significantly reduce cavity formation.

The ingots were then homogenized for 7 d at 1100° C. under a slow purge of the same reducing atmosphere. A hydraulic press was used to flatten the ingots to ˜3 mm thickness (FIG. 1, panel (c)) after which they were machined roughly rectangular. Successive cold rolling reduced the ingot down to a 100 μm foil (FIG. 1, panel (d)) in ˜130 passes. An additional ˜10 passes further reduced a subset of the foil to 50 μm which is the current limit of our rolling mill capability.

### 2.2 6-81 Molybdenum Alloy [6-81 Mo]

Half of the fluxgates cores manufactured for this experiment were constructed from an alloy similar to the historical 6-81 Mo permalloy (English and Chin, 1967; Odani, 1964; Pfeifer, 1966; Pfeifer and Boll, 1969; Scanlon, 1966) combined by weight from 6% molybdenum, 81.3% nickel, and the remainder iron. The 6-81 alloy was first proposed for fluxgate use by Gordon et al. (1968) and has been used by several groups worldwide Including Infinetics Inc., Müller et al., (1998), and Musmann (2010). The historical 6-81 alloys included ˜0.5% manganese which is a common alloy additive to improve hot working, notionally by binding to sulphur contaminants. The historical 6-81 melts were hot rolled (Gordon and others, 1968), but our own melts were not, and therefore we did not include any manganese.

### 2.3 28-62 Copper Alloy [28-62 Cu]

The second half of the fluxgate cores shown here were manufactured using a ferromagnetic alloy, mentioned in Narod (2014), that that we hypothesized has potential to produce high-quality fluxgate cores. This 28-62 Cu alloy was combined by weight from 28% copper, 62% nickel and the remainder iron. This ratio was derived from the theoretical framework established by Narod (2014) and prior experimental results from v. Auwers and Neumann (1935) who explored a wide range of iron-nickel-copper alloys searching for high initial permeability. V. Auwers and Neumann (1935) presented their work in a special printing from the Scientific Publications of the Siemens-Factory that was not circulated to the public.

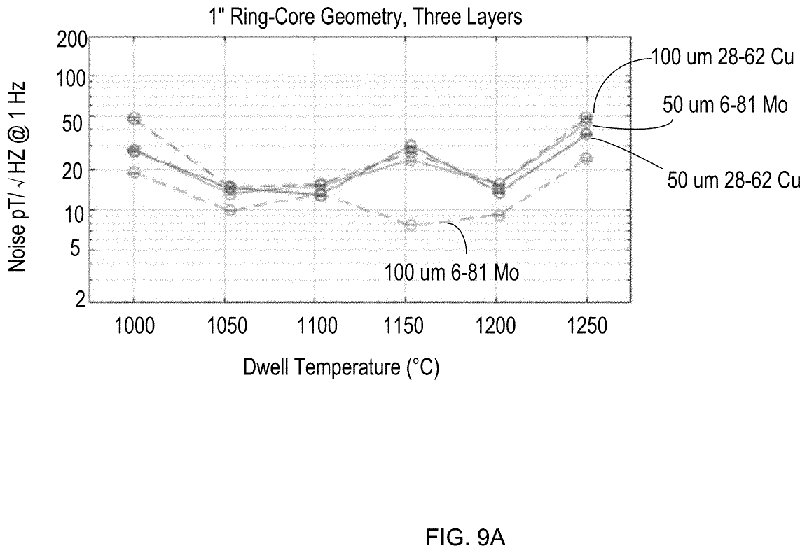

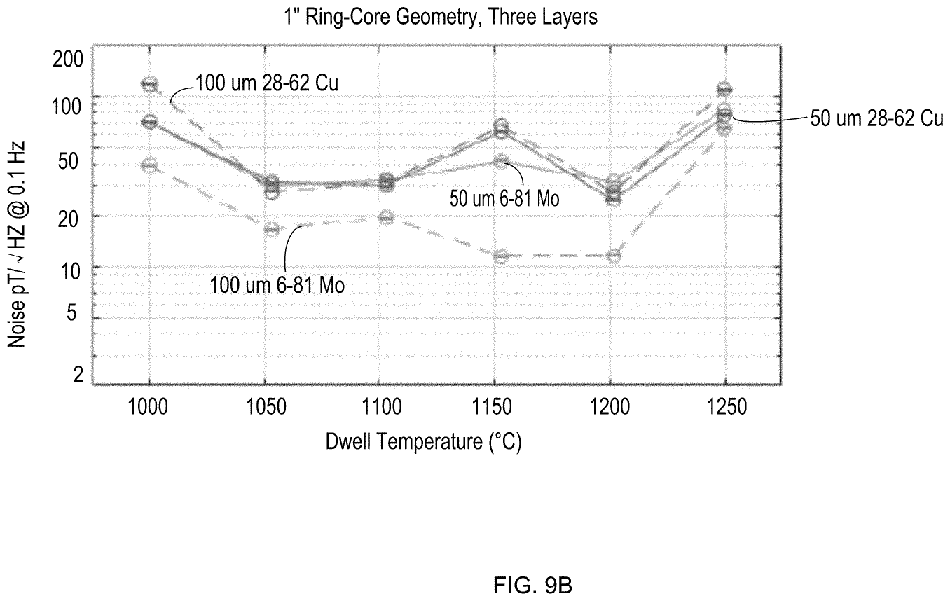

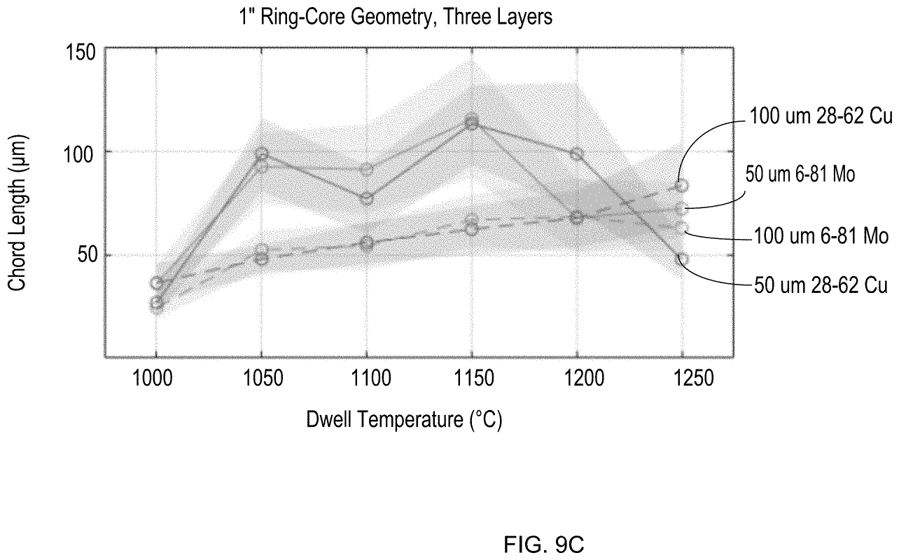

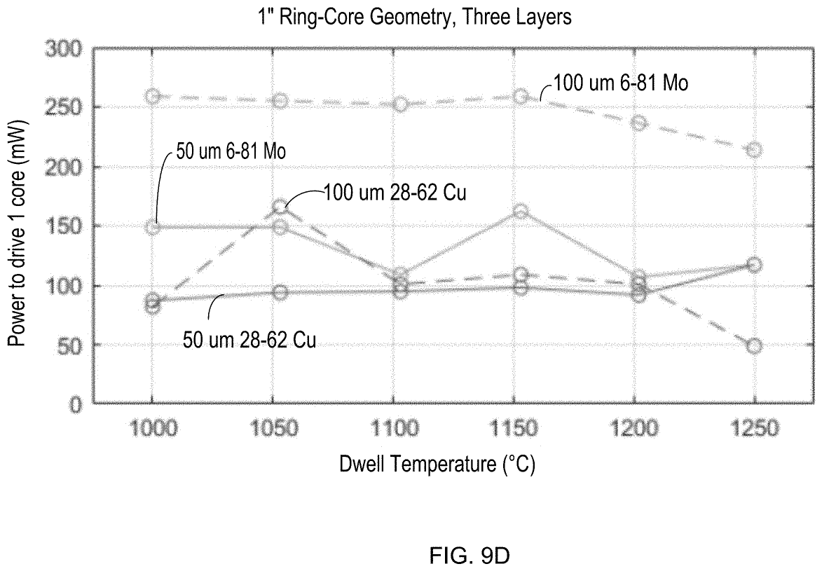

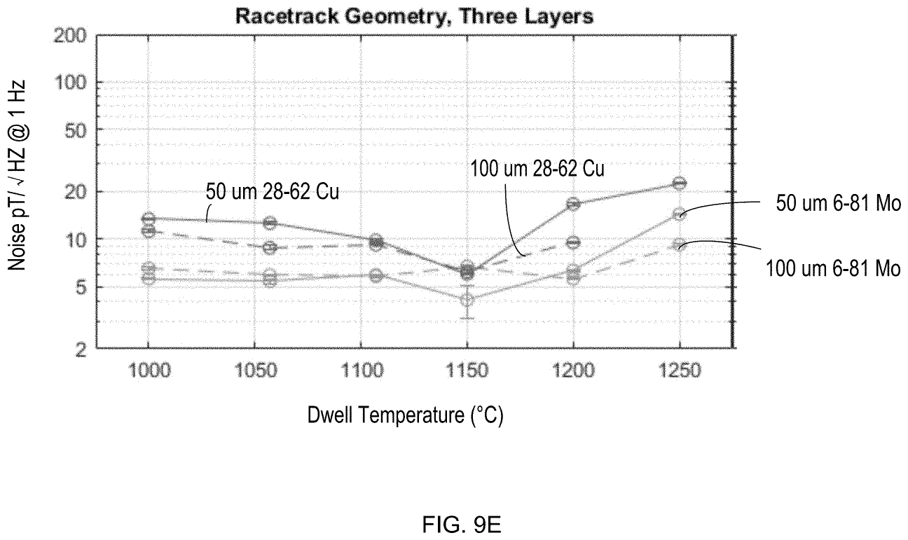

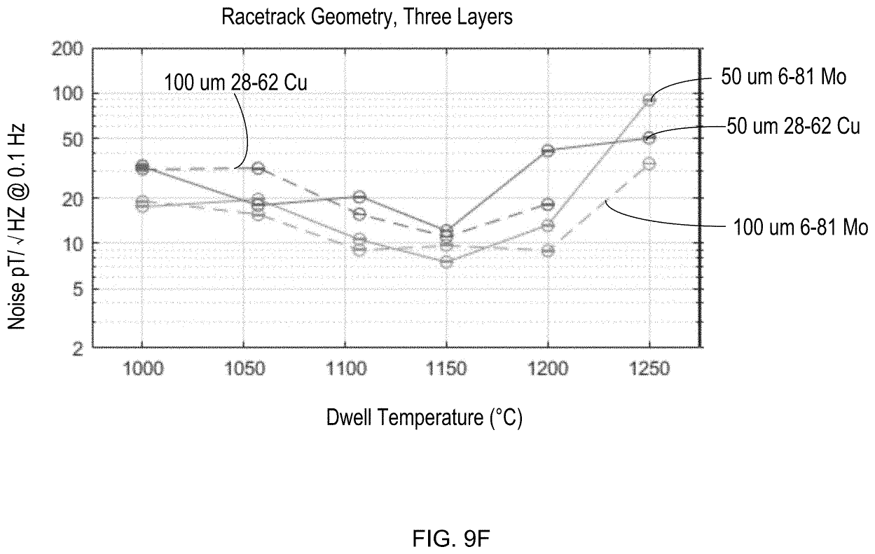

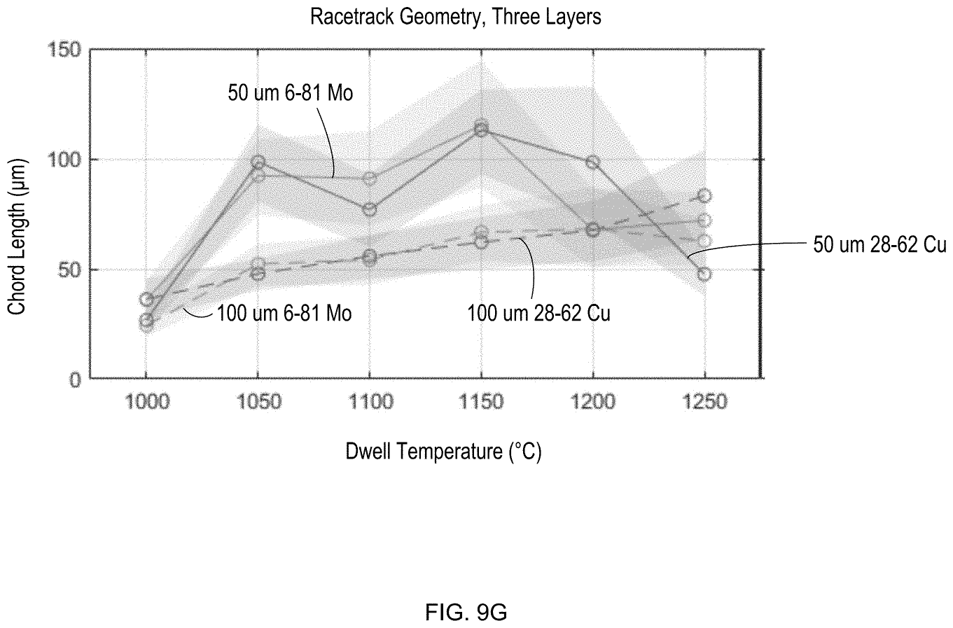

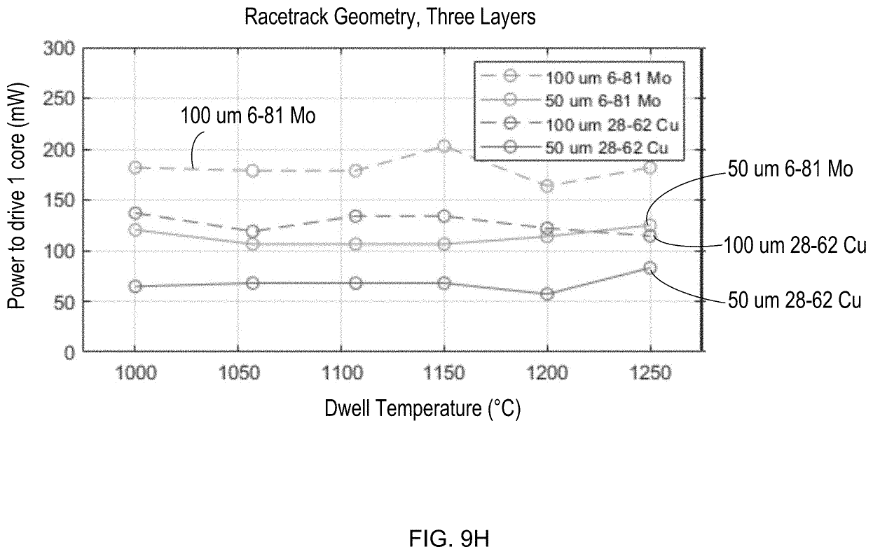

The choice of 28-62 Cu for a first trial copper alloy resulted from an examination of v. Auwers and Neuman (1935) FIGS. 9,12 and 14, which graph magnetic property data for a large range of iron-nickel-copper alloys, for a heat treatment process roughly similar the ones used in our own experimental efforts. According to these old graphs, 28-62 Cu simultaneously maximizes initial magnetic permeability and minimizes magnetostriction. These are both indicators for minimum magnetic anisotropy, which according to Narod (2014) leads to the reduction of magnetostatic energy in the material and which is a direct diagnostic for improved magnetic noise. It is also the case that 28-62 Cu has expected magnetic saturation induction, Bs, like that of 6-81 Mo permalloy. Both theoretical calculations in Narod (2014) and Bs data graphed in v. Auwers and Neuman (1935) lead to that result. For both experimental observation and theoretical reasons Bs is a lead indicator for magnetic noise (Narod et al, 1985; Mussmann, 2010; Narod, 2014). 28-62 Cu's expected lower Bs of 0.5-0.6 T should be advantageous.

### 2.4 Ring-core and Racetrack Variants

Two styles of fluxgate cores were manufactured to explore the impact of geometry. The classic Infinetics S1000 1″ ring-core geometry was used as the standard design. We also manufactured cores in an alternative racetrack geometry (Gordon et al., 1965; Hinnrichs et al., 2000, 2001; Ripka, 1990, 1993, 2000) that combines the symmetry and closed flux path of a ring-core with the high single-axis geometric gain of a parallel rod core. The race-track geometry also allowed us to experiment with several design changes that were intended to increase reproducibility and reduce power consumptions.

### 2.5 1″ Ring-Cores

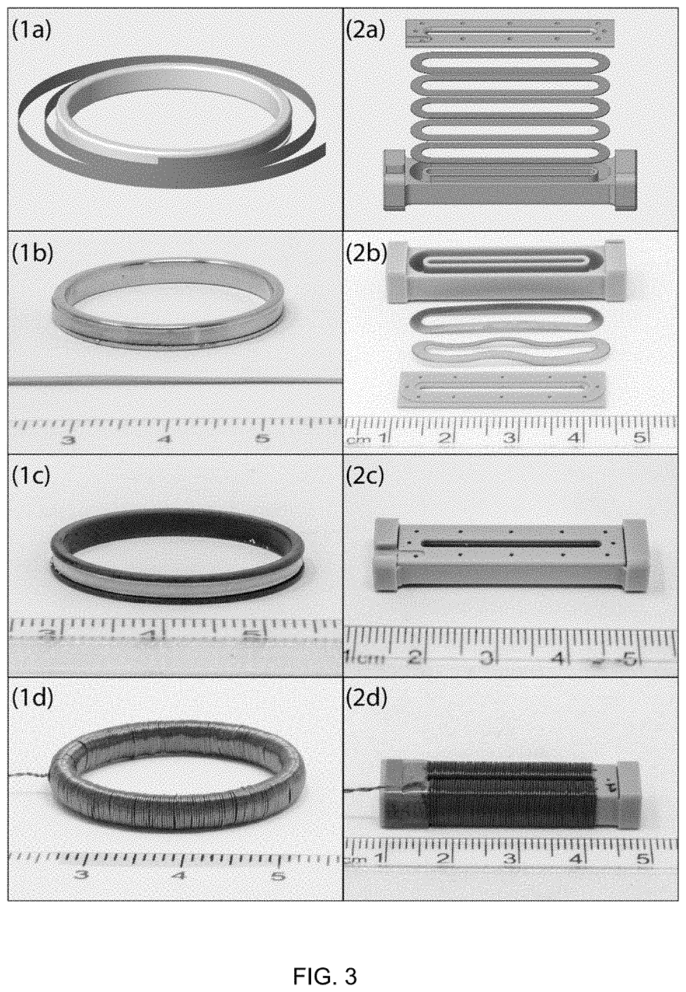

The 1″ ring-cores were manufactured following the description in Miles et al., (2019) as shown in FIG. 3 (1a-1d). Permalloy foil was sheared into strips sufficiently long for three layers. Each strip was spot welded to the Inconel bobbin, dilute milk of magnesia was applied and dried, the foil was wound three times, and spot welded to itself aligned to the start point. The assembled ring-cores were heat-treated with variations of the standard process heat-treatment as described below. The ring-cores were then insulated with Mylar tape, toroidal drive windings of AWG 32 magnetic wire were applied, and the leads were terminated in a twisted pair.

### 2.6 Racetrack Cores

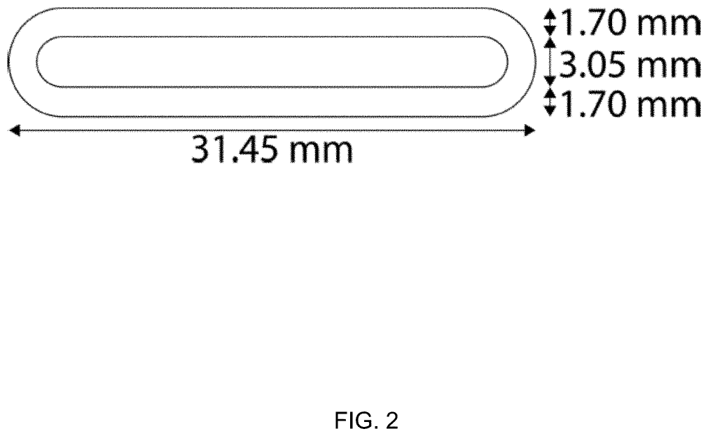

The racetrack design makes several fundamental changes beyond the gross geometry of the core assembly as shown in FIG. 3 (panels 2a-2d). The permalloy foil was cut to ˜5 cm length, stacked, drilled, and secured in a tight bundle. A computer numerical control (CNC) mill was used to machine continuous 6.45 mm wide by 31.45 mm long racetrack foil washers (FIG. 2). The track width was machined to 1.70 mm. The gap was sized to comfortably accommodate hand winding of a toroidal drive winding.

No insulating coating is applied; rather the racetrack washers are placed in the furnace bare and heat-treated using variations of the standard process heat-treatment as described below, prior to being assembled into a core. Heat-treated foils were then stacked into a non-conductive plastic bobbin (Delrin for prototypes, 30% glass filled PEEK for production) interleaved with insulating layers of Kapton of the same geometry. A plastic lid closed the core and supports a quasi-toroidal drive of AWG 32 magnet wire. Production cores have the foil wet-set into a polymer to prevent the foil layers from moving during the magnetizing drive pulses. We are investigating foil movement as a source of long-term offset shifts.

The stacked foil washers remove the need to spot-weld the ferromagnetic element, as is done in traditional spiral-wound sensors, avoiding the heat-effected area around the weld and the associated unpredictable magnetic properties. Heat-treating the foil washers individually removes the risk of undesired welding between layers and between the foil and the standard metal Inconel bobbin that can cause unintended shorting. This process also eliminates the differential strains between Inconel and Permalloy, that invariably happens when cooling the assembly from 1100° C. to room temperature. The race-track geometry aligns ferromagnetic mass on one axis, potentially producing lower noise; however, the race-track geometry cannot be double-wound like a ring-core to sample two orthogonal components. The quasi-toroidal drive windings are time-consuming to apply, but the closed flux path of the racetrack should reduce stray fields and offsets error compared to traditional parallel rod sensors.

### 2.7 Heat Treatment

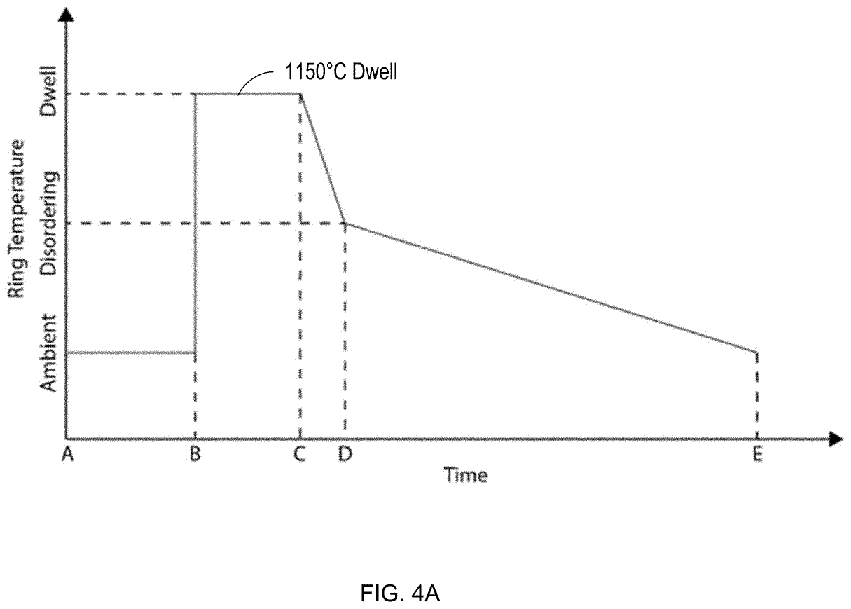

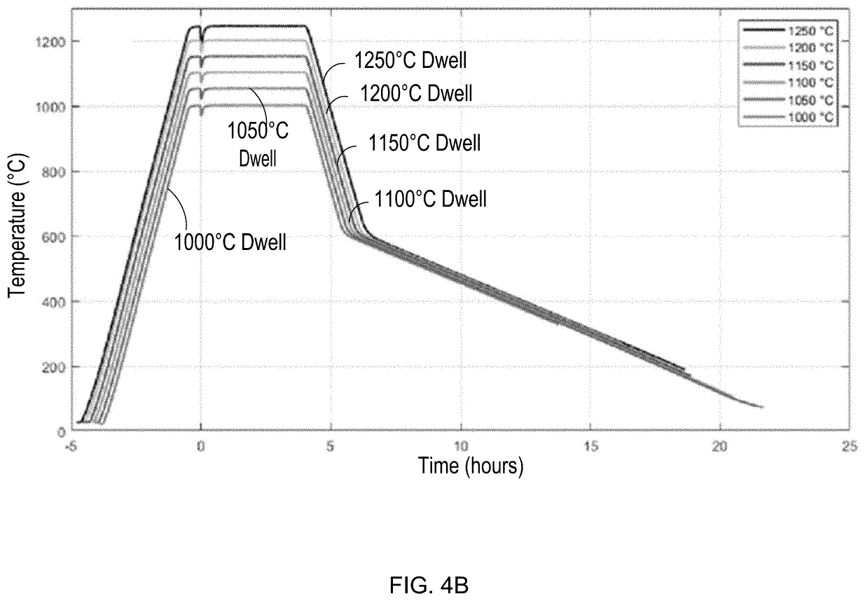

The heat treatments used here are adapted from the profile (FIG. 4A) of Miles et al. (2019) which are, in turn, based loosely on a description given by Gordon et al. (1968). The heat treatment starts with the ferromagnetic material at room temperature (A) and comprises four steps: rapid heating (B) of the ferromagnetic material by insertion into the pre-heated furnace, a fixed length dwell (B-C), ramping down to the upper limit of the critical ordering range (C-D), and finally a slow ramp to room temperature (D-E). This profile follows the theory of Narod (2014) with the goal of developing the largest possible grains in the given thickness of the permalloy foil, enhancing primary recrystallisation through rapid heating, and suppressing secondary recrystallisation by rapidly cooling to the disordering range.

The furnace was preheated to the dwell temperature at 300° C. per hour, the fastest rate suggested by the manufacturer to avoid cracking the Alumina work tube by thermal shock. Ramp (C-D) was completed at −300° C. per hour for the same reason. Ramp (D-E) was completed at −35° C. per hour as suggested by Gordon et al. (1968). The transition point (D) was set at 600° C. at the upper limited of the critical ordering range for 6-81 permalloy suggested by Gordon et al. (1968). To explore the effect of the heat treatment we standardised on a 4 h dwell at temperatures ranging from 1000 to 1250° C. as shown in FIG. 4B. The transient dip in the dwell temperature occurs when the room temperature permalloy, and the boat used to transport it, are slid into the hot zone of the furnace. All heat treatments were completed under a continuous slow purge of a reducing atmosphere of 10% hydrogen diluted in argon.

### 3 Core Characterisation

A common electronics package was used to drive each ring-core, measure the power consumption required, and characterize its power spectral density noise floor. In addition, foil coupons for each alloy and thickness were included in each heat treatment so that the grain size could be characterized optically.

### 3.1 Fluxgate Core Characterisation Setup

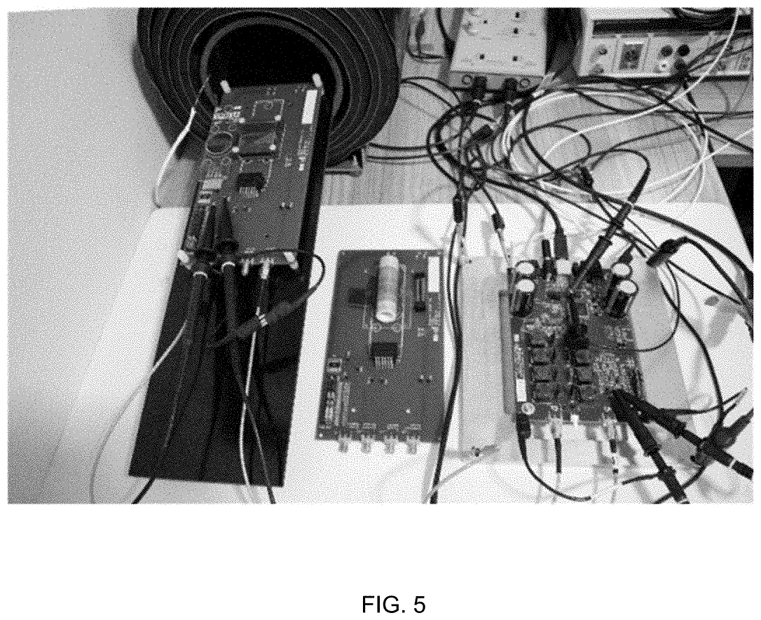

The various fluxgate cores where characterised using a process similar to that described in Miles et al., (2019). A common, single-axis electronics package was used to drive and sample each fluxgate core. The 1 in. ring-cores were paired with a rectangular solenoidal sense winding similar to that used in Wallis et al., (2015) while the racetrack cores were paired with a tubular solenoidal sense coil matching their geometry (FIG. 5). Fixturing allowed these sense windings to be aligned with a large solenoid, used to generate a calibration magnetic field, mounted within a five-layer MuMetal shield.

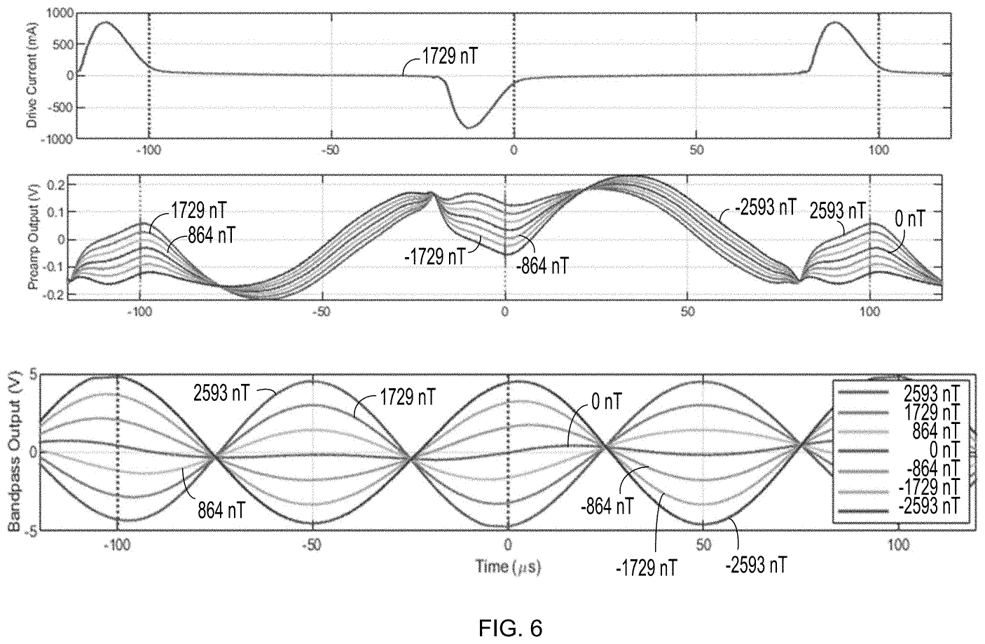

A common electronics package was used to drive all cores using ±7.5V at 5.0 kHz. Both legs of the drive circuit used 1850 μH series inductors to create the resonant drive condition. For each core, the shunt capacitance was increased until symmetric current pulses were observed through the drive winding showing that minimum resonance had been achieved (FIG. 6, top)—then 50% additional capacitance was added.

A common shorted-coil topology preamplifier was used for both sense windings. Several cores coupled large amounts of the 1 F current waveform into the output of the sensor (FIG. 6, middle). To avoid electrical clipping of the pre-amplifier we standardized on a common 555Ω feedback resistance. Although low, this accommodated all the cores shown in this experiment and provided a common comparison. A high Q bandpass filter at the 10.0 kHz 2 F frequency acted as the anti-aliasing filter and provided 37 dB of gain for the fluxgate action. The filtered signal (FIG. 6, bottom) was digitized at 10.0 ksps and box-car average decimated to 100 sps before being telemetered to a computer for analysis.

### 3.2 Noise Floor Characterisation

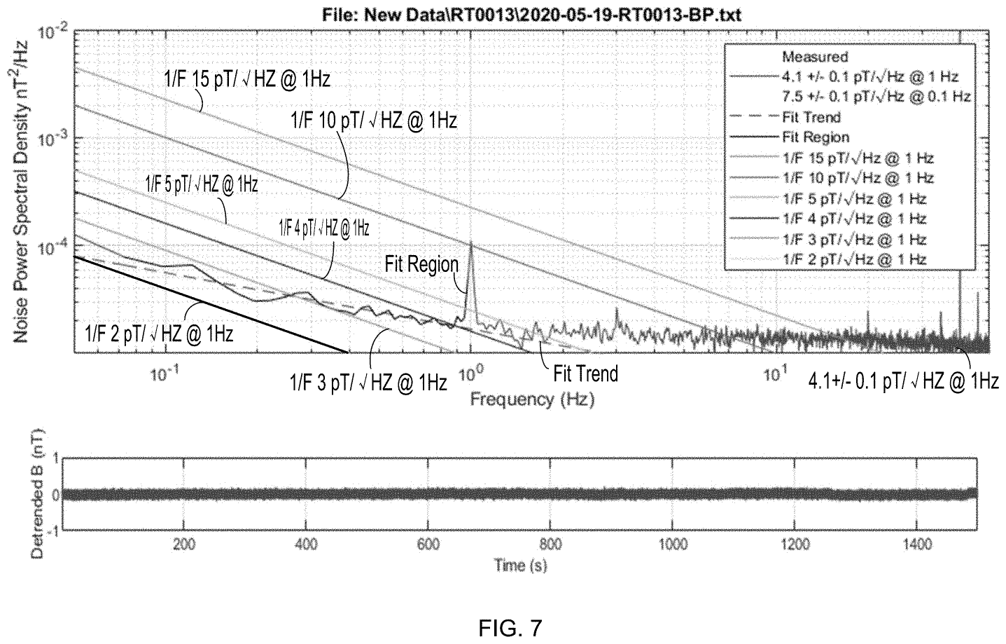

A known-amplitude sinusoidal magnetic test signal was applied to the solenoid inside the five-layer MuMetal shield using a signal generator and a 10 k low-tempco resistor. The phasing of the direct digitization was adjusted to maximize the amplitude of the measured test signal. A linear scaling coefficient was then adjusted until the visualization software showed the test signal with the correct amplitude to calibrate the sensitivity of the complete single-axis magnetometer now formed around the fluxgate core under test. The 1 Hz test signal was then disabled, and 30 minutes of quiet data were taken with the core and sensor inside the magnetic shield. Welch's method of overlapped periodograms (100 sps, 4096-point fast Fourier transform (FFT), Hann window, 75% overlap) was used to estimate the power spectral density noise floor as shown in FIG. 7.

Two figures of merit were established to simplify comparing core performance. Robust linear regression (MATLAB robustfit) was used to fit a linear trend to the noise floor from 0.05 to 1.0 Hz to exclude local and instrumental narrow-band noise. This trendline was evaluated at 1 Hz to produce the standard pT/√Hz at 1 Hz noise metric. We also evaluated the trendline at 0.1 Hz to reflect the updated INERMAGNET data requirement (Turbitt et al., 2013) for long period measurements, which has moved the noise requirement by a decade from 10 pT/√Hz at 1 Hz to 10 pT/√Hz at 0.1 Hz. The narrow bandwidth feature in FIG. 7 is electronics noise related to data telemetry and is not relevant to the fluxgate core noise investigation.

This fitting technique provides a robust, quantitative estimate of the intrinsic magnetic noise of the core despite instrumental noise at 1 Hz due to telemetry and several intermittent narrow-band magnetic noise sources in the test environment. FIG. 7 shows the noise floor for a racetrack core with a measured noise of 4.1±0.1 pT/√Hz at 1 Hz. It is interesting to note that the noise below 1 Hz seems to trend significantly below the historically referenced 1/F trend. This needs to be investigated further with a lower-noise preamplifier to exclude the possibility that the true trend is being masked by comparably high broadband digitizer noise.

### 3.3 Power Consumption Characterization

The drive circuit was powered by its own benchtop power supply allowing the ±0.5 mA resolution of the power required to drive each core. The drive frequency, drive voltage, and series inductance were held constant for all tests. The capacitance required to achieve resonant drive was determined empirically as described above. Power consumption for each core was measured after each core had stabilized by operating for at least 60 seconds.

### 3.4 Grain Size Characterisation

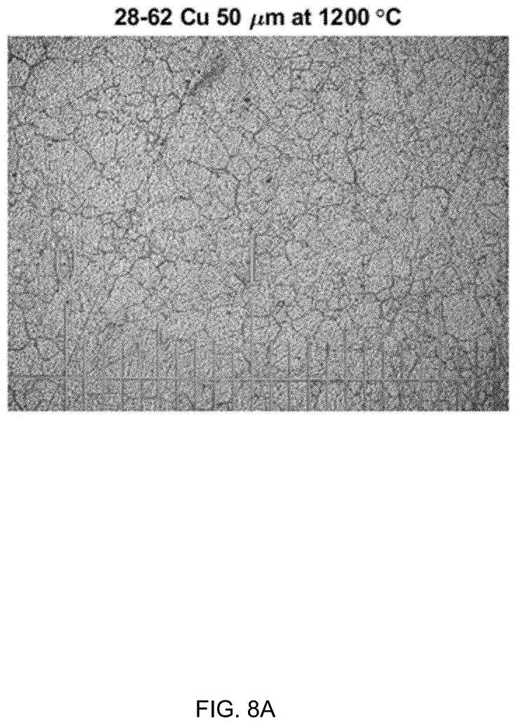

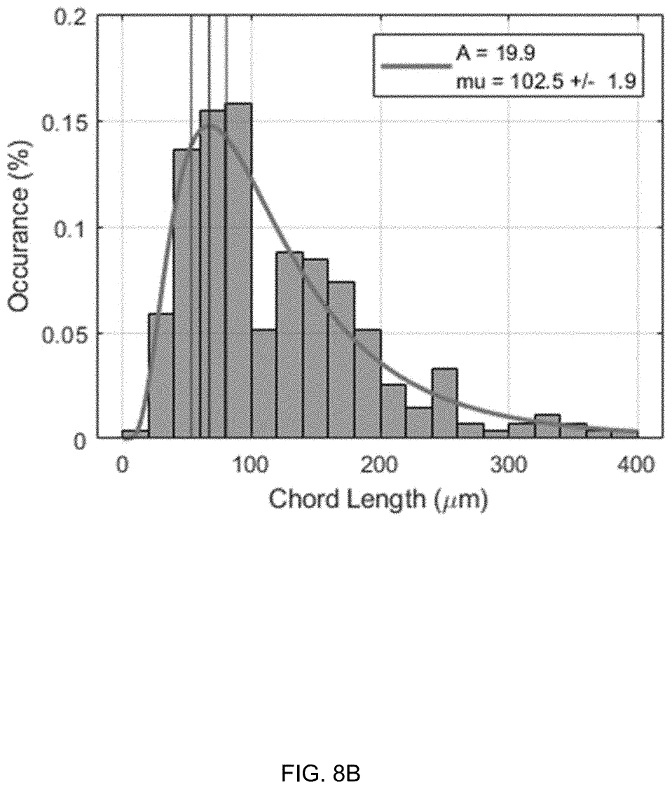

Each heat treatment included 10×10 mm coupons for each combination of metallurgy and foil thickness. These coupons were used to estimate the grain size of the heat-treated material. Each coupon was photographed with a graticule for scale, using a widefield metallurgical inverted microscope under polarized visible light to emphasize the grain boundaries that had developed in the material as shown in FIG. 8A.

Grain size was estimated using the intercept method (Abrams, 1971) as implemented by the MATLAB linecut software package by Meister (2020). Lines are drawn across the sample and chord lengths are determined by eye each time a grain boundary is crossed. The distribution of chord lengths was fit to a log-normal curve (FIG. 8B) as

$$y = \frac{A}{{xa}_{σ} \sqrt{2 π}} {e}^{( - \frac{{( log x - log {a}_{μ} )}^{2}}{2 {( log {a}_{σ} )}^{2}} )}$$

For cross-comparison, each distribution was characterized by the mode of its probability density function (vertical blue line) plus or minus 10% up and down from that point on the cumulative density function (vertical lines).

### 3.5 Core Performance

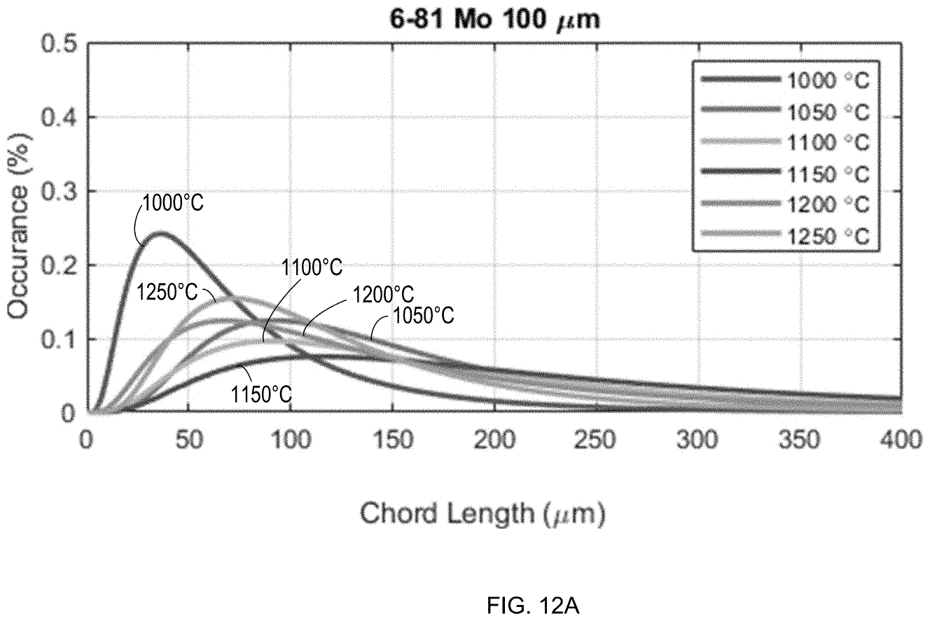

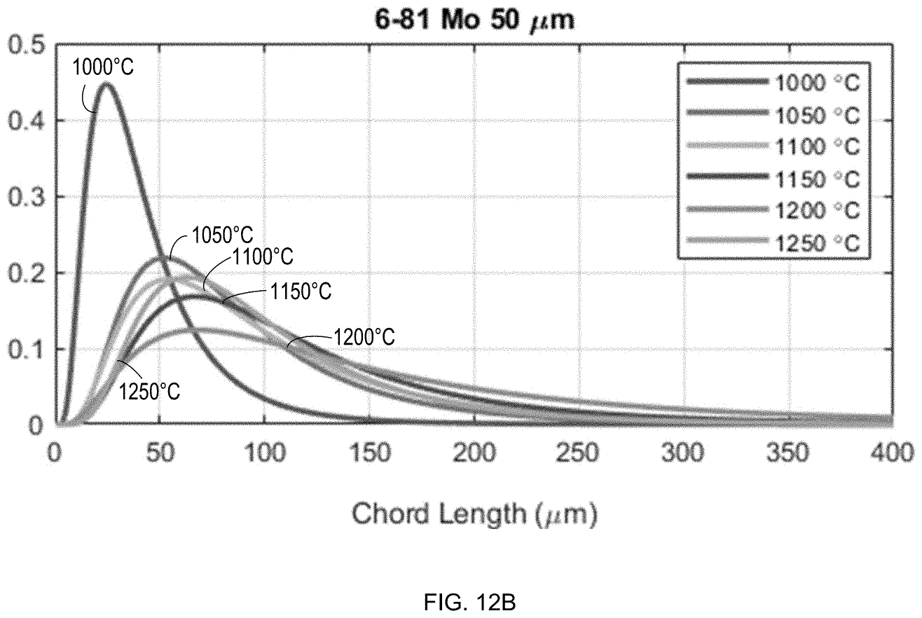

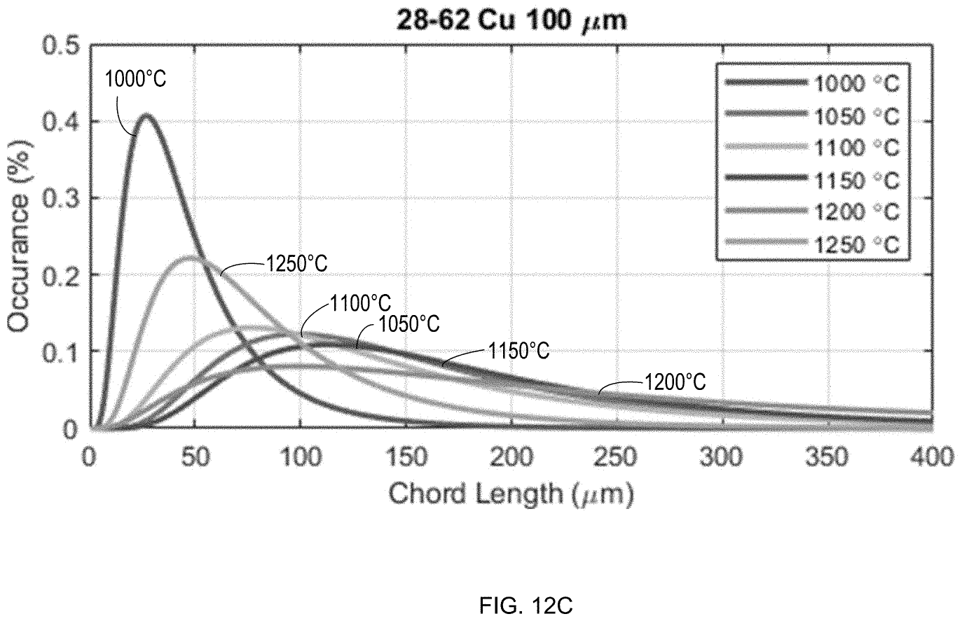

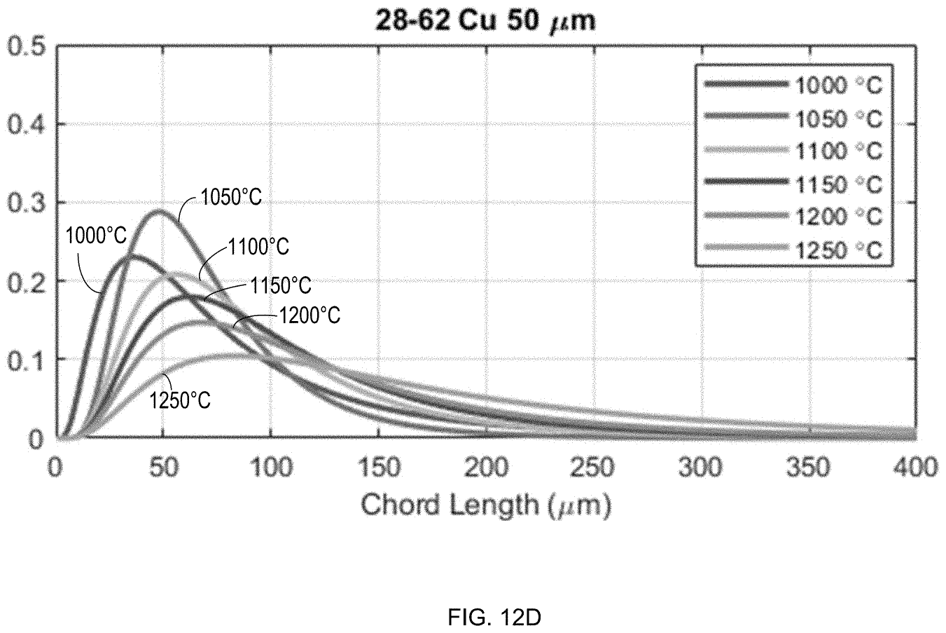

FIG. 9A-FIG. 9H summarize the results of the parameter sweep of cores manufactured and tested for this experiment. FIGS. 9A, 9B, 9C, and 9D show cores manufactured using the tradition lin. ring-core geometry while FIGS. 9E, 9F, 9G, and 9H show the new racetrack design. FIG. 9A and FIG. 9B (and FIGS. 9E, 9F) show the measured intrinsic magnetic noise of the cores at 1 Hz and 0.1 Hz, respectively. FIG. 9C (and FIG. 9G) estimates the grain size observed in the foil coupon using the mode of a log-normal fit to the measured chord size distribution (FIG. 12A, 12B, 12C, 12D) plus or minus the 10% of the corresponding cumulative density function. Only a single foil coupon was manufactured for each alloy, thickness, and heat treatment but the data is shown for clarity. FIG. 9D and FIG. 9H show additional power required to drive each core. Both the 6-81 Mo alloy and the 28-62 Cu alloy are shown. Finally, dashed lines indicate 100 μm foil while solid lines show 50 μm. The 100 μm 28-62 Cu racetrack core heat-treated at 1250° C. dwell coupled large amounts of 1 F drive tone through the sensor saturating the pre-amplifier so its noise measurement has been excluded.

Each point in FIG. 9A to FIG. 9H corresponds to a single fluxgate core and individual cores performance is likely to vary similar to the distribution shown in FIG. 3 of Narod (2014). Therefore, we expect significant variance in the individual datapoints in addition to the experimental uncertainty that is shown by the error bars. Overall trends in the data should be robust but individual datapoints should not be over-interpreted. Several trends are apparent.

The ring-core noise at 1 Hz, noise at 0.1 Hz, and power consumption varied more than the equivalent racetracks performance. We cannot isolate the origin of this variation from the current dataset but speculate it may result from inconsistency in the welding process used to attach the spiral wound foil in the 1″ ring-core or due to inadvertent welding when the complete 1 in. ring core assembly is heat treated. Regardless, many of the same trends are observed in both the ring core and racetrack data.

The 50 and 100 μm foils produced broadly similar intrinsic magnetic noise. This was not expected since, as all the cores in FIG. 9A-9H contain three layers, the 50 μm cores contain half as much ferromagnetic material as the 100 μm cores. Conversely, the lowest noise Infinetics rings known used a 12-μm foil so this may suggest 50 μm is still above the optimum foil thickness.

The measured noise as a function of heat-treatment dwell temperature, for all rings, geometries, and frequencies, are generally concave upward with minima around 1150° C. suggesting this may be the local optimum. The 100 μm foils require more power than the equivalent 50 μm foils. In the racetrack geometry cores, the thicker foils require between 1.5 and 2 times more power. The ring-cores show an equivalent trend in 6-81 Mo while the 28-62 Cu shows a much smaller effect. More generally, the racetrack cores require less power than their ring-core counterparts—despite containing more ferromagnetic material and generally providing lower noise. Both core designs have a comparable drive winding resistance of 1.5-1.9Ω, so it seems likely that the power difference results from eddy current losses in the conductive Inconel X750 bobbin used in the 1 in. ring core that have no equivalent in the insulating plastic bobbins used in the racetrack cores.

Optical grain size analysis of the foil coupons showed a consistent pattern of larger grain size and larger spread with increasing heat treatment temperature in the 50 μm foil consistent with accelerated grain growth at higher temperatures. The 100 μm foil cores show a maximum in grain size at 1150° C. dwell temperature but with wider variation. We speculate that the grains in the 100 μm foil may not span the entire thickness of the foil so the optical analysis of the surface is sampling various cross sections and providing less representative values. Couderchon et al. (1989) potentially saw a similar plateau in grain size.

The 28-62 Cu material provides surprisingly respectable noise performance for a first attempt at a new alloy. Compared to the traditional 6-81 Mo alloy, 28-62 Cu provides noise performance ranging from equal to twice as noisy. However, the power required to drive the 28-62 Cu cores is roughly 30% lower than comparable 6-81 Mo cores.

The race-track cores simultaneously provide lower noise and lower power consumption that their comparable ring-core. The power advantage will be partially offset by the need for at least three race-track cores per sensor whereas only two are required for a double-wound ring-core sensor.

3.6 Effect of the slow Quench and Sub-Curie Heat Treatment

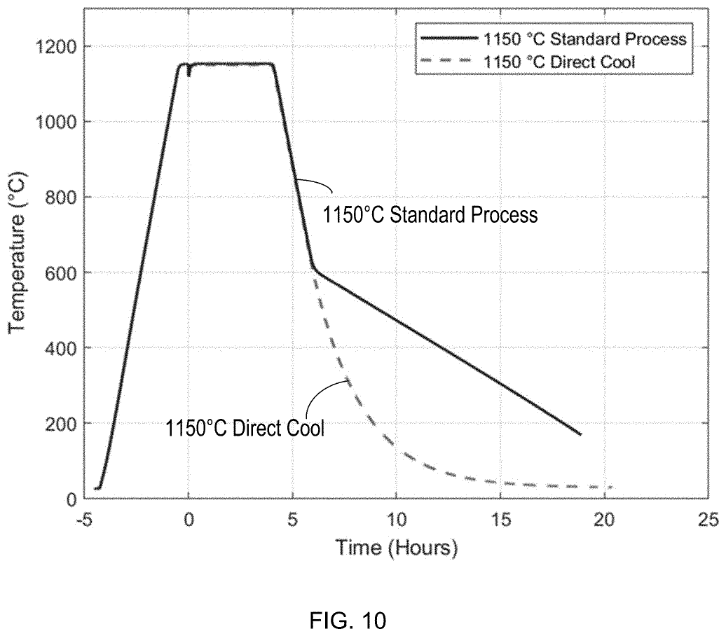

One heat treatment was accidently programmed to skip the second slow cool at −35° C. per hour ramp suggested by Gordon et al. (1968). Rather, the furnace attempted to ramp down to room temperature at −300° C. per hour directly as shown in FIG. 10—the actual ramp rate being slower and low temperatures due to the thermal mass of the furnace. This provided an opportunity to investigate the effect of this long-tail in the heat treatment.

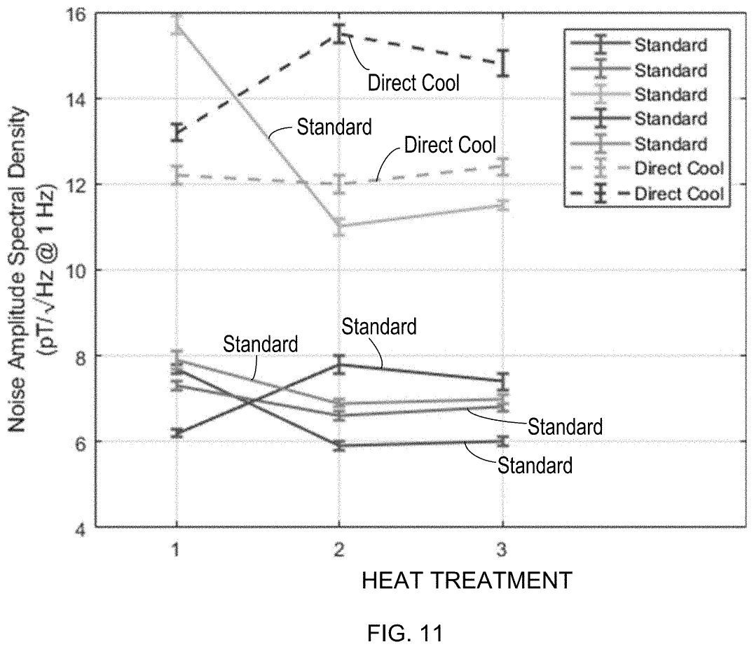

The two resulting ring-cores (FIG. 11, dashed) had an average initial noise level of ˜13 pT/√Hz at 1 Hz. An equivalent set of five cores processed immediately beforehand (FIG. 11, solid) with the standard long-tail heat treatment had an average initial noise of ˜9 pT/√Hz at 1 Hz. Two additional heat treatments were executed to investigate whether this discrepancy was related to the cooling rate or simply time at elevated temperature below the Curie temperature. All seven rings were subjected to two rounds of an additional 100 h at 100° C. described in Narod (2014). The initial 100 h at 100° C. improved the noise floor of the five rings manufactured with the standard heat treatment by an average of 16% while the second 100 h at 100° C. heat treatment provided no significant benefit. The two rings manufactured with the direct cool heat treatment showed no significant additional improvement from either 100 h at 100° C. heat treatment.

### 3.7 Grain Size

FIG. 12 shows the distributions fitted to the chord (grain size) measurements for each alloy, foil thickness, and heat treatment. In general, hotter heat treatments increase the median chord length and broaden the distribution with 50 μm 28-62 Cu alloy showing the most consistent ordering. The trend appears to break at the 1250° C. temperature which corresponds (FIGS. 9A-9H) to the increasing trend in magnetic noise. We hypothesize that higher soak temperatures lead to the formation of fewer primary recrystallization initiation sites, simply because there is less time available before the dislocation energy is consumed. Thus, there are fewer grains left after primary recrystallization.

### 3.8 Effect of Number of Layers

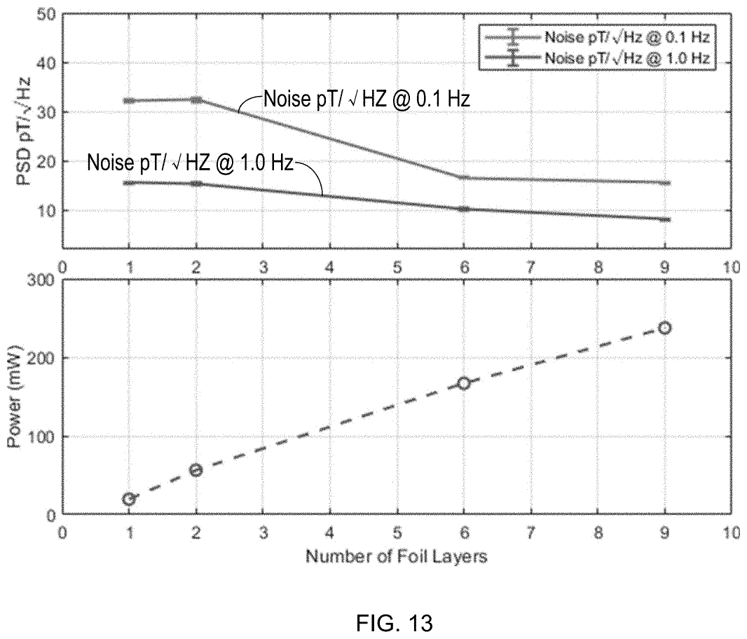

A batch of four racetrack cores were manufactured to explore the relationship between magnetic noise, power consumption, and the number of foil layers. The four cores contained 1, 2, 6, and 9 layers of 50 μm 28-62 Cu alloy and had a common heat treatment. FIG. 13 shows that increasing the number of foil layers decreases the magnetic noise at 0.1 and 1.0 Hz with the effect diminishing between 6 and 9 layers. Power consumption increases linearly with the number of layers.

### 3.9 Noise Distribution

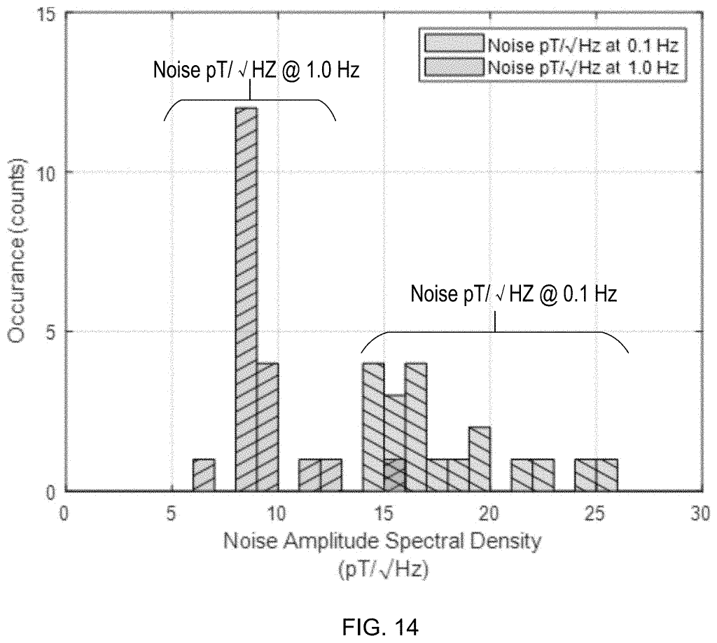

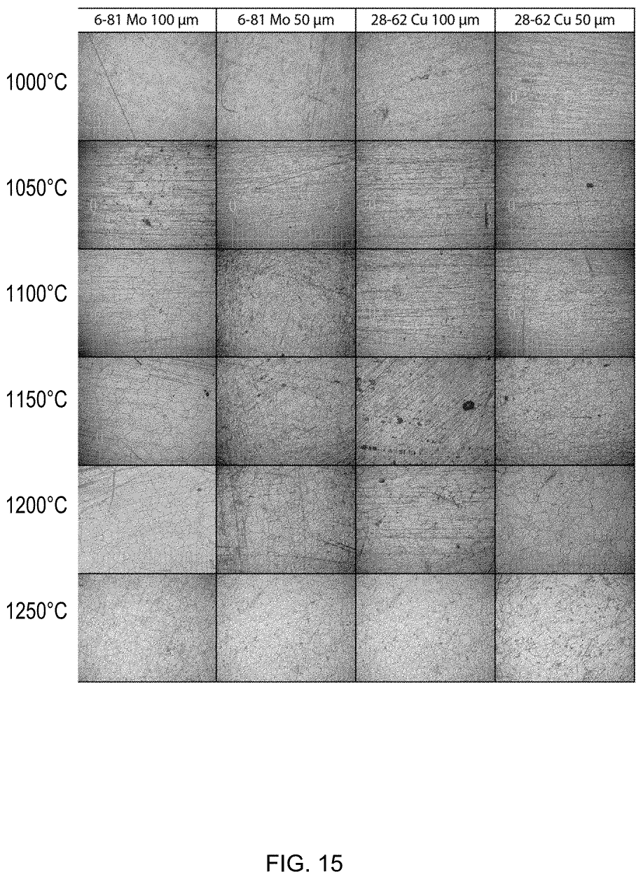

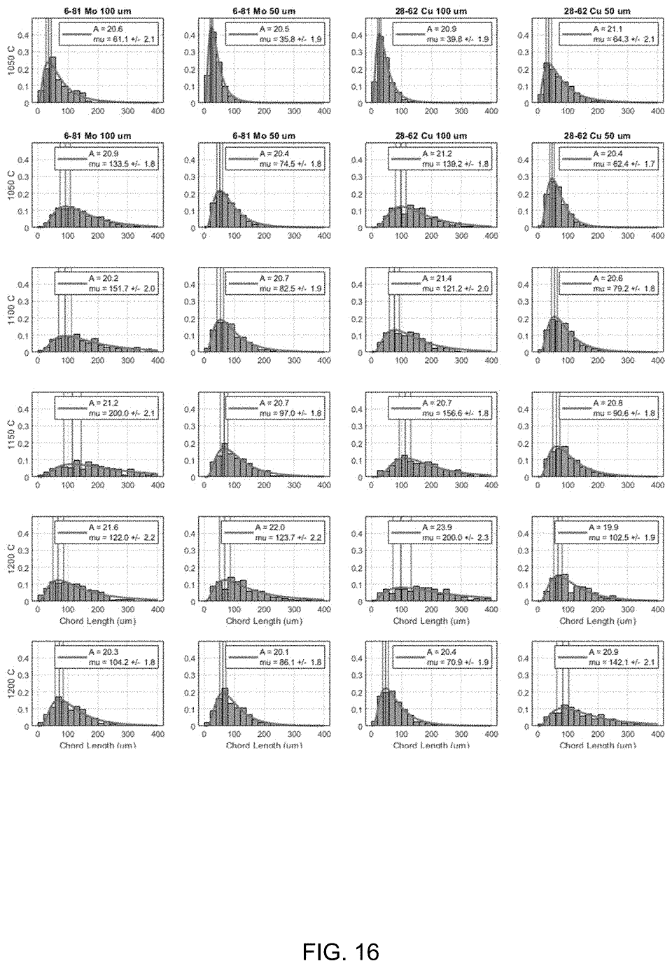

We manufactured twenty notionally identical racetrack cores to test the noise variability of the manufacturing process. All rings were three layers of 50 μm 28-62 μm foil heat-treated with a dwell temperature of 1150° C. FIG. 14 shows a histogram of the noise floor distributions showing peaks at ˜16 pT/√Hz at 0.1 Hz and 9 pT/√Hz at 1 Hz.

### 4 Conclusions

The race-track washer design seems to offer several advantages over the traditional 1 in. spiral-wound ring core: more consistent yield in noise performance, significantly fewer high-noise outliers, and lower noise performance at equal or lower power consumption per core. These advantages will be partially offset by the need for at least one core per measurement axis (three cores per sensor) whereas ring-cores can be double wound (two cores per sensor). In general, the 50 μm foils outperform the 100 μm foils in terms of noise per drive power.

In this disclosure, we have introduced a novel, low-noise and low-power nickel alloy we have designated 28-62Cu permalloy. It comprises, by weight, 28% Cu, 62% Ni, Fe balance. This alloy is suggested by data published in von Auwers and Neumann (1935) and theory in Narod (2014). In 1935, high-Cu-content permalloys were investigated for more typical, high-saturation induction applications and fell out of favour. We believe that we are the first investigators since then to revisit Cu permalloys and specifically with regard to fluxgate sensors where lower saturation induction is advantageous.

The 6-81 Mo alloy generally produces lower noise than the 28-62 Cu alloy all other variables held equal. However, the 28-62 requires significantly lower power. The consistent grain size and evolution shown by the 50 μm coupon suggests that the grains developed in the foil may be spanning the entire thickness of the foil whereas in the 100 μm foils the grains may not penetrate the complete thickness. The 1150° C. dwell temperature appears to provide the lowest noise for all alloy and foil thickness combinations. Directly cooling at 300° C. per hour down to room temperature appears to significantly degrade noise performance in a way that cannot be improved by subsequent sub-curie heat treatment. However, the 100 hours at 100° C. sub-curie secondary heat-treatment offers a significant improvement in cores manufactured using the standard process suggesting it be added to the standard process or the second cooling rate be decreased. Additional layers of foil appear to reduce the magnetic noise until approximately six to nine layers. Each additional foil layer causes a linear increase in the power consumption.

### 5 Options, Variations, and Alternatives

These results suggest that thinner foils may yield superior noise and power performance which is consistent with 12.5 μm foil used in the best historical Infinetics cores. We are currently developing improved rolling mill capacity with the intention of investigating 25 and 12.5 μm foils. In general, a racetrack geometry core containing more layers of thinner copper alloy foil seems like a promising path to consistently manufacturable, low-noise and low-power fluxgate cores. Alloy 28-62Cu was chosen as the first copper alloy trial due to it having magnetic properties similar to those of 6-81Mo in the molybdenum permalloy composition range (Pfeifer and Boll, 1969). 28-62Cu has approximately zero magnetostriction and has minimum magnetocrystalline anisotropy, as evidenced by its local maximum initial permeability and minimum coercivity, with all these properties achieved by identical heat treatment.

The test of the alloy 28-62Cu was a preliminary study. Based on these results, we have begun an extensive survey of alloys of nearby compositions, guided by magnetic properties data presented in von Auwers and Neumann (1935).

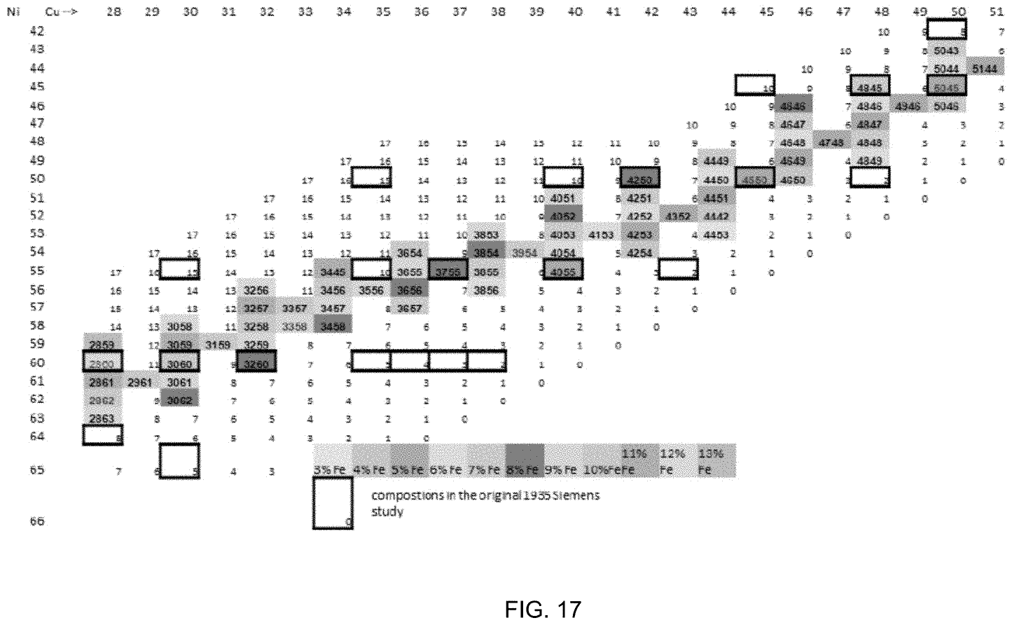

In particular, alloy samples have been fabricated for material analysis following the zero magnetostriction Cu alloy regime from Auwers and Neumann (1935) and shown in the cells in FIG. 17. We expect this regime to have high initial magnetic permeability and low magnetostriction making it theoretically likely to have low magnetostatic energy and therefore low intrinsic magnetic noise.

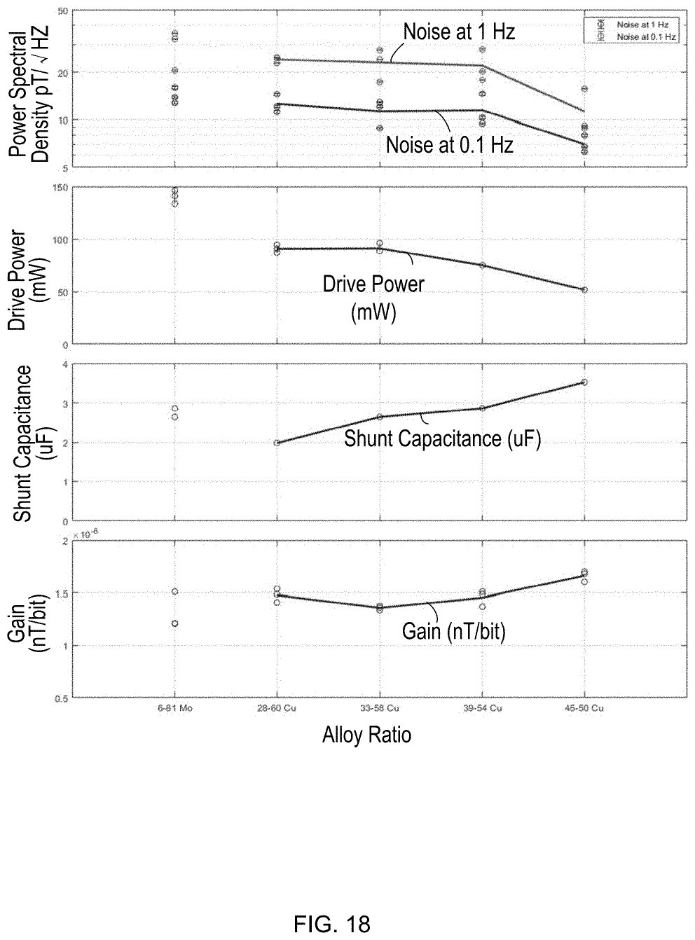

The alloys are currently being processed and prepared for analysis. However, three prototype fluxgate cores have been fabricated at 28-60 Cu, 33-58 Cu, 39-54 Cu, and 45-50 Cu. Twelve cores, three of each alloy, were compared to a matched trio of cores manufactured from traditional 6-81 Mo manufactured in the same batch (FIG. 18). In general, we find that the two primary figures of merit for a fluxgate, intrinsic magnetic noise and drive power, both decrease as the copper composition increases up to at least 45-50 Cu. This suggests that the higher copper alloys are extremely promising for fluxgate sensors and magnetic shields and that the optimum alloy may require higher than 45% Cu.

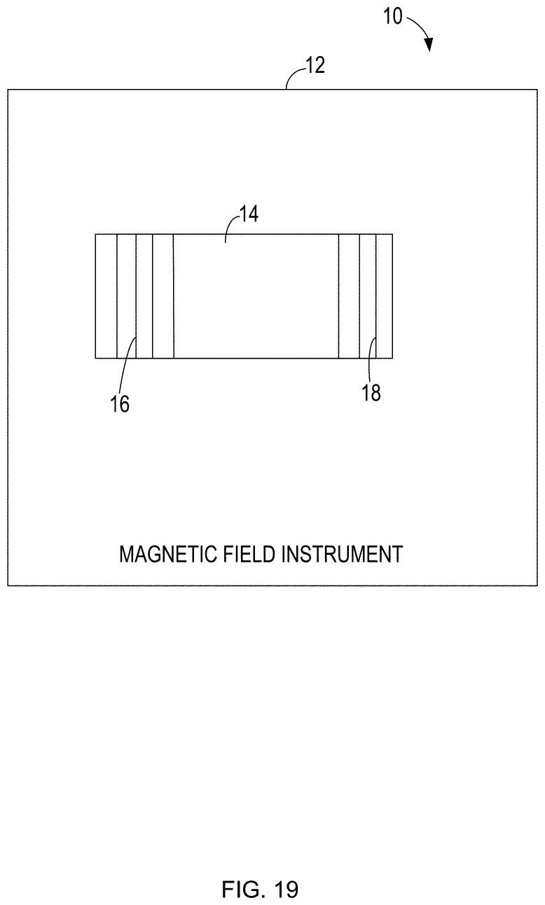

We plan to cover a composition range from 28% to 55% copper and covering the zero magnetostriction range. We will be examining DC resistivity, coercivity, saturation moment, initial and maximum differential permeability, magnetostriction, Curie temperature, grain size, and grain growth fabrics with some of these properties examined at temperatures from room temperature to Curie temperature. These results suggest that thinner foils may yield superior noise and power performance which is consistent with 12.5 μm foil used in the best historical Infinetics cores. The present invention may be used with 25 and 12.5 μm foils. The 28-62 Cu alloy is promising in terms of noise relative to drive power. Generally, race-track geometry core containing more layers of thinner copper alloy foil may provide for consistently manufacturable, low-noise and low-power fluxgate cores. FIG. 19 is a block diagram of one example of a magnetic field instrument 10 such as a magnetometer. The magnetic field instrument 10 may have a housing 12. The magnetic field instrument 10 may have a magnetometer core body 14 and a sense winding 16 and drive winding 18. The sense winding 16 may be formed from a set of coil turns and may be electrically connected to appropriate electronics. The drive winding 18 may be formed from a set of coil turns. The magnetometer core body may be a racetrack core or a ring core or otherwise as shown or described herein.

Although various specific embodiments have been shown and described herein, it is to be contemplated that numerous options, variations, and alternatives are contemplated. This includes variation in the thickness of foils, the number of layers of foil used in a core, the manner in which the foil is used to construct a core, the ratio of elements in the alloy, the heat treatment, the geometry of the core, and other variations.

It is also contemplated that the alloy may be used for applications such as magnetic shielding. For example, foil or other thin layers of the composition may be provide for low field magnetic shielding in applications where shielding alloys based on molybdenum are insufficient.

The foregoing description has been presented for purposes of illustration and description. It is not intended to be an exhaustive list or limit any of the invention to the precise forms disclosed. It is contemplated that other alternatives or exemplary aspects are considered included in the invention. The description is merely examples of embodiments, processes or methods of the invention. It is understood that any other modifications, substitutions, and/or additions can be made, which are within the intended spirit and scope of the invention.

### REFERENCES

Abrams, H.: Grain size measurement by the intercept method, Metallography, 4, 59-78, https://doi.org/10.1016/0026-0800(71)90005-X, 1971.
Couderchon, G., Porteseil, J. L., Bertotti, G., Fiorillo, F., and Soardo, G. P.: Magnetization process in NiFe alloys with vanishing anisotropies, IEEE T. Magn., 25, 3973-3975, 1989.
English, A. T. and Chin, G. Y.: Metallurgy and magnetic properties control in permalloy, J. Appl. Phys., 38, 1183-1187, 1967.
Fornacon, K.-H., Auster, H. U., Georgescu, E., Baumjohann, W., Glassmeier, K.-H., Haerendel, G., Rustenbach, J., and Dunlop, M.: The magnetic field experiment onboard Equator-S and its scientific possibilities, Ann. Geophys., 17, 1521-1527, https://doi.org/10.1007/s00585-999-1521-3, 1999.
Gordon, D., Lundsten, R., and Chiarodo, R.: Factors affecting the sensitivity of gamma-level ringcore magnetometers, IEEE T. Magn., 1, 330-337, https://doi.org/10.1109/TMAG.1965.1062987, 1965.
Gordon, D., Lundsten, R., Chiarodo, R., and Helms, H.: A fluxgate sensor of high stability for low field magnetometry, IEEE T. Magn., 4, 397-401, 1968.
Hinnrichs, C., Pels, C., and Schilling, M.: Noise and linearity of a fluxgate magnetometer in racetrack geometry, J. Appl. Phys., 87, 7085-7087, https://doi.org/10.1063/1.372939, 2000.
Hinnrichs, C., Stahl, J., Kuchenbrandt, K., and Schilling, M.: Dependence of sensitivity and noise of fluxgate sensors on racetrack geometry, IEEE T. Magn., 37, 1983-1985, https://doi.org/10.1109/20.951028, 2001.
Janosek, M.: Parallel Fluxgate Magnetometers, in: High Sensitivity Magnetometers, edited by: Grosz, A., Haji-Sheikh, M. J., and Mukhopadhyay, S. C., Springer International Publishing, Cham, 41-61, https://doi.org/10.1007/978-3-319-34070-8_2, 2017.
Meister, S.: grain and particle analysis with line intersection method, MATLAB Central File Exchange, https://www.mathworks.com/matlabcentrak/fileexchange/35203-grain-and-particle-analysis-with-line-intersection-method (last access: 1 Mar. 2022), 2020.
Miles, D. M., Ciurzynski, M., Barona, D., Narod, B. B., Bennest, J. R., Kale, A., Lessard, M., Milling, D. K., Larson, J., and Mann, I. R.: Low-noise permalloy ring cores for fluxgate magnetometers, Geosci. Instrum. Method. Data Syst., 8, 227-240, https://doi.org/10.5194/gi-8-227-2019, 2019.
Moldovanu, C., Brauer, P., Nielsen, 0. V., and Petersen, J. R.: The noise of the Vacquier type sensors referred to changes of the sensor geometrical dimensions, Sensor. Actuat. A-Phys., 81, 197-199, https://doi.org/10.1016/S0924-4247(99)00087-4, 2000.
Müller, M., Lederer, T., Fornacon, K. H., and Schäfer, R.: Grain structure, coercivity and high-frequency noise in soft magnetic Fe-81Ni-6Mo alloys, J. Magn. Magn. Mater., 177, 231-232, 1998.
Musmann, G.: Fluxgate magnetometers for space research, BoD—Books on Demand, 2010.
Narod, B. B.: The origin of noise and magnetic hysteresis in crystalline permalloy ring-core fluxgate sensors, Geosci. Instrum. Method. Data Syst., 3, 201-210, https://doi.org/10.5194/gi-3-201-2014, 2014.
Narod, B. B., Bennest, J. R., Strom-Olsen, J. O., Nezil, F., and Dunlap, R. A.: An evaluation of the noise performance of Fe, Co, Si, and B amorphous alloys in ring-core fluxgate magnetometers, Can. J. Phys., 63, 1468-1472, 1985.
Odani, Y.: Magnetic Properties of Cube-Textured 6-81:3Mo-Permalloy, J. Appl. Phys., 35, 865-866, 1964.
Pfeifer, F.: Zum Verständnis der magnetischen Eigenschaften technischer Permalloylegierungen, Z. Met., 57, 295, 1966.
Pfeifer, F. and Boll, R.: New soft magnetic alloys for applications in modern electrotechnics and electronics, IEEE T. Magn., 5, 365-370, 1969.
Primdahl, F.: The fluxgate magnetometer, J. Phys. E Sci. Instrum., 12, 241, 1979.
Ripka, P.: Improved fluxgate for compasses and position sensors, J. Magn. Magn. Mater., 83, 543-544, https://doi.org/10.1016/0304-8853(90)90618-Z, 1990.
Ripka, P.: Race-track fluxgate sensors, Sensor. Actuat. A-Phys., 37-38, 417-421, https://doi.org/10.1016/0924-4247(93)80071-N, 1993.
Ripka, P.: Race-track fluxgate with adjustable feedthrough, Sensor. Actuat. A-Phys., 85, 227-231, https://doi.org/10.1016/S0924-4247(00)00394-0, 2000.
Scanlon, W. W.: Solid state research of the Applied Physics Department for the year 1965, Naval Ordnance Lab, White Oak, MD, 1966.
Scarzello, J. F., Holmes, J. J., and O'keefe, E. C.: Integrating fluxgate magnetometer, US Department of Navy, U.S. Pat. No. 6,278,272, 2001.
Sene, F. F. and Motta, C. C.: Synthesis and characterization of Ni—Mo filler brazing alloy for Mo—W joining for microwave tube technology, Mater. Res., 16, 417-423, https://doi.org/10.1590/S1516-14392013005000019, 2013.
Snare, R. C.: A History of Vector Magnetometry in Space, in: Measurement Techniques in Space Plasmas Fields, edited by: Pfaff, R. F., Borovsky, J. E., and Young, D. T., American Geophysical Union, 101-114, https://doi.org/10.1002/9781118664391.ch12, 1998.
Turbitt, C., Matzka, J., Rasson, J., St-Louis, B., and Stewart, D.: An instrument performance and data quality standard for intermagnet one-second data exchange, in: Proceedings of the XVth IAGA Workshop on Geomagnetic Observatory Instruments, Data Acquisition, and Processing, XVth IAGAWorkshop on Geomagnetic Observatory Instruments and Data Processing, 4-14 Jun. 2012, Cadiz, Spain, 186-188, 2013.
von Auwers, O. and Neumann, H.: Über Eisen-Nickel-Kupfer-Legierungen hoher Anfangspermeabilität, Spec. Print. Sci. Publ. Siemens-Fact., XIV, 92-108, 1935.
Wallis, D. D., Miles, D. M., Narod, B. B., Bennest, J. R., Murphy, K. R., Mann, I. R., and Yau, A. W.: The CASSIOPE/e-POP Magnetic Field Instrument (MGF), Space Sci. Rev., 189, 27-39, https://doi.org/10.1007/s11214-014-0105-z, 2015.

What is claimed is:

1. A metal alloy comprising by weight percentage of the metal alloy, 28 to 55 percent copper, 45 to 63 percent nickel, and 4 to 10 percent iron.

2. The metal alloy of claim 1 wherein the metal comprises by weight percentage 28 percent copper, 62 percent nickel, and 10 percent iron.

3. Magnetic shielding formed by one or more layers of the metal alloy of claim 1.

4. A foil comprising the metal alloy of claim 1.

5. The foil of claim 4 wherein the foil has a thickness of 100 μm or less.

6. A magnetic field instrument comprising a magnetometer core body comprising the foil of claim 5.

7. The magnetic field instrument of claim 6 wherein the magnetometer core body is a ring core formed from a single strip of the foil wound into a spiral.

8. The magnetic field instrument of claim 6 wherein the magnetometer core body is a racetrack core formed from a plurality of stacked layers of the foil.

9. The magnetic field instrument of claim 6 further comprising a sense winding around the magnetometer core body.

10. The magnetic field instrument of claim 9 further comprising a drive winding around the magnetometer core body.

11. The magnetic field instrument of claim 6 wherein the magnetic field instrument is configured as a fluxgate magnetometer.

12. A magnetic field instrument comprising:
a magnetometer core body formed from a permalloy comprising copper, iron, and nickel; and
a first set of coil turns around the magnetometer core body forming a sense winding.

13. The magnetic field instrument of claim 12 wherein the permalloy comprises a plurality of layers of permalloy foil.

14. The magnetic field instrument of claim 13 wherein the permalloy consists of by weight percent of the permalloy, 28 to 55 percent copper, 45 to 63 percent nickel, and 4 to 10 percent iron.

15. The magnetic field instrument of claim 14 wherein each of the plurality of layers of the permalloy foil have a thickness of 100 μm or less.

16. The magnetic field instrument of claim 12 wherein the magnetometer core body is a ring core.

17. The magnetic field instrument of claim 12 wherein the magnetometer core body is a racetrack core.

18. The magnetic field instrument of claim 12 wherein the plurality of layers of the permalloy foil have a thickness of 50 μm or less.

19. A method of manufacturing a magnetic field instrument, the method comprising:
forming metal alloy comprising by weight percentage of the metal alloy, 28 to 55 percent copper, 45 to 63 percent nickel, and 4 to 10 percent iron;
rolling the metal alloy to form a foil;
constructing a magnetometer core using the foil; and
adding a sense winding to the magnetometer core.

20. The method of claim 19 further comprising heat treating the magnetometer core.
